(19) United States
(12) Patent Application Publication
(10) Pub. No.: US 2009/0172335 A1
(43) Pub. Date: Jul. 2, 2009

(54) FLASH DEVICES WITH RAID

(76) Inventors: Anand Krishnamurthi Kulkarni, San Jose, CA (US); Marco Sanvido, Belmont, CA (US)

Correspondence Address: PATTERSON & SHERIDAN, L.L.P., 3040 POST OAK BLVD., SUITE 1500, HOUSTON, TX, 77056, US

(21) Appl. No.: 11/968,147

(22) Filed: Dec. 31, 2007

(51) Int. Cl. G11C 7/00

(52) U.S. Cl. 711/170

(57) ABSTRACT

Methods and apparatus of the present invention include multiple flash storage devices that are configured to form a single storage device that is flexible and scalable. Reliability and performance are improved while keeping the power consumption benefits compared to conventional hard disk drives.

### BACKGROUND OF THE INVENTION

1. Field of the Invention

Embodiments of the present invention generally relate to flash memory devices and, more particularly, to configuring multiple flash memory devices to form a single storage device.

2. Description of the Related Art

Conventional redundant array of independent disks/drives (RAID) systems use hard disk drives to store data rather than using inexpensive flash storage devices. Flash storage devices are not able to provide the necessary bandwidth for read and writes and have high error rates due to read disturb times and write disturb times. Furthermore, the need for managing wear leveling complicates the distribution of data on the flash storage devices. Additionally, flash memory devices have long erase and program times. Therefore, flash storage devices have not displaced magnetic media storage devices.

This presents the need for a system configured to use multiple flash storage devices to form a single storage device, reducing the system cost while overcoming some of the limitations of the flash storage devices.

### SUMMARY OF THE INVENTION

Flash storage devices are configured to form a single storage device to improve the reliability and performance while keeping the power consumption benefits compared to conventional hard disk drives. Using the flash storage devices provides flexibility and scalability by storing data in a first portion of the flash storage devices and storing redundancy information, such as error correction codes, parity, or metadata, in a second portion of the flash storage devices.

Various embodiments of the invention provide a method for configuring multiple flash storage devices to form a single storage device include configuring a first portion of the multiple flash storage devices to store data in stripes and configuring a second portion of the multiple flash storage devices to store error correction information. The error correction information for a stripe of data is computed as the stripe of data is written to the first portion of the multiple flash storage devices and the error correction information for the stripe of data is stored in the second portion of the multiple flash storage devices.

Various embodiments of the invention provide a system for configuring multiple flash storage devices to form a single storage device that includes of the multiple flash storage devices and a flash storage controller. The multiple flash storage devices include a first portion of the flash storage devices configured to store data in stripes and a second portion of the multiple flash storage devices configured to store error correction information. The flash storage controller is configured to store the data in the stripes in the first portion of the multiple flash storage devices, compute the error correction information, and store the error correction information in the second portion of the multiple flash storage devices.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates an example system including a single storage device formed by multiple flash devices.

FIGS. 2A, 2B, and 2C illustrate example striping configurations for the flash devices.

FIGS. 3A and 3B illustrate example striping configurations with error correction for the flash devices.

FIG. 4A is an example configuration using multiple flash devices, in accordance with an embodiment of the method of the invention.

FIG. 4B is a flow chart of operations for restoring data, in accordance with an embodiment of the method of the invention.

FIG. 5 is another example configuration using multiple flash devices, in accordance with an embodiment of the method of the invention.

### DETAILED DESCRIPTION

In the following, reference is made to embodiments of the invention. However, it should be understood that the invention is not limited to specific described embodiments. Instead, any combination of the following features and elements, whether related to different embodiments or not, is contemplated to implement and practice the invention. Furthermore, in various embodiments the invention provides numerous advantages over the prior art. However, although embodiments of the invention may achieve advantages over other possible solutions and/or over the prior art, whether or not a particular advantage is achieved by a given embodiment is not limiting of the invention. Thus, the following aspects, features, embodiments and advantages are merely illustrative and, unless explicitly present, are not considered elements or limitations of the appended claims.

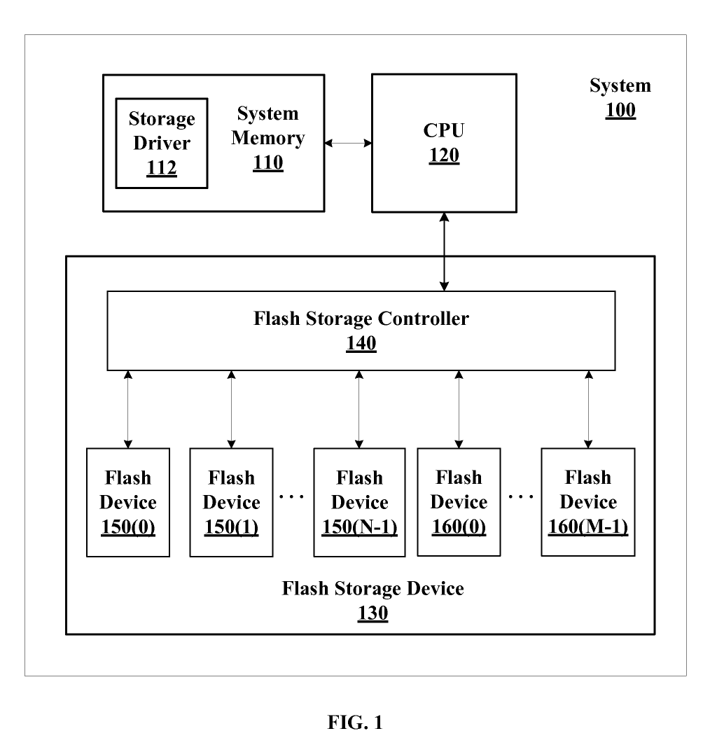

FIG. 1 is a block diagram of an exemplary embodiment of a respective system 100 in accordance with one or more aspects of the present invention. System 100 includes a central processing unit, CPU 120, a system memory 110, a flash storage controller 140, and a flash storage device 130. System 100 may be a desktop computer, server, laptop computer, palm-sized computer, tablet computer, game console, portable wireless terminal such as a personal digital assistant (PDA) or cellular telephone, computer based simulator, or the like. CPU 120 may include a system memory controller to interface directly to system memory 110. In alternate embodiments of the present invention, CPU 120 may communicate with system memory 110 through a system interface, e.g., I/O (input/output) interface or a bridge device.

Flash storage controller 140 is coupled to CPU 120 via a high bandwidth interface. In some embodiments of the present invention the high bandwidth interface is a standard conventional interface such as a peripheral component interface (PCI) hypertransport protocol. Flash storage controller 140 may be configured to function as a RAID 5 controller, a RAID 0 controller, a RAID 1 controller, or the like. In other embodiments of the present invention, the I/O interface, bridge device, or flash storage controller 140 may include additional ports such as universal serial bus (USB), accelerated graphics port (AGP), and the like.

Flash storage device 130 includes one or more storage devices, specifically flash memory devices that are each directly coupled to flash storage controller 140 to provide a high bandwidth interface for reading and writing the flash memory devices. In some configurations of the present invention, N flash devices 150(0) through 150(N−1) are configured to store data and M flash devices 160(0) through 160(M−1) are configured to store redundancy and metadata information. The redundancy may be parity or error code correction (ECC) information for error detection and correction. The metadata may also include wear leveling information, bad sector information, directory information, journal data, and the like.

Each flash device within flash storage device 130, e.g., flash device 150(0), 150(1), 150(N−1), 160(0), 160(M−1), and the like, may be replaced or removed, so at any particular time, system 100 may include fewer or more flash devices. Flash storage controller 140 facilitates data transfers between CPU 120 and flash storage device 130, including transfers for performing parity functions. Alternatively, parity computations are performed by flash storage controller 140. In some embodiments of the present invention, multiple flash devices 150(0) through 150(N−1) and 160(0) through 160(M−1) are packaged in a multi-chip-module with or without flash storage controller 140. Alternatively, flash devices 150(0) through 150(N−1) and 160(0) through 160(M−1) are interconnected on a printed circuit board, or integrated on a single silicon chip, with or without flash storage controller 140. Flash devices 150(0) through 150(N−1) are collectively referred to as flash devices 150. Likewise, flash devices 160(0) through 160(M−1) are collectively referred to as flash devices 160. Flash devices 150 and 160 may also include some or all functions of 140 that may or may not be utilized.

In some embodiments of the present invention, flash storage controller 140 performs block striping and/or data mirroring based on instructions received from storage driver 112. Each flash device 150 or 160 coupled to flash storage controller 140 includes drive electronics that control storing and reading of data within the flash device 150 or 160. Data is passed between flash storage controller 140 and each flash device 150 or 160 via a bidirectional bus. Each flash device 150 or 160 may also include circuitry that controls detection and mapping out of failed portions of the storage circuitry based on bad sector information.

System memory 110 stores programs and data used by CPU 120, including storage driver 112. Storage driver 112 communicates between the operating system (OS) and flash storage controller 140 to perform RAID management functions such as detection and reporting of flash device failures, maintaining state data, e.g., bad sectors, address translation information, and the like, for each flash device within flash storage device 130, and transferring data between system memory 110 and flash storage device 130.

An advantage of using flash storage devices within flash storage device 130 is that the configuration is flexible and scalable. Additional flash storage devices may be included in flash storage device 130 to increase the storage capacity and flash storage controller 140 may configure flash devices 150 and 160 to implement a variety of different RAID systems, e.g., RAID 0, RAID 1, and the like. Multi level cell (MLC) flash devices may be used for flash devices 150 and 160 instead of more expensive single level cell (SLC) flash devices in order to reduce cost while not increasing the overall error rate. Alternatively, a combination of MLC and SLC flash devices can be used within flash storage device 130. Furthermore, the different flash devices may have different page and block sizes and be provided by different device vendors. Flash storage controller 140 may manage wear leveling on flash devices 150 and 160 at the device, page, block, or array level. Additionally, flash storage controller 140 may map out failing flash devices or portions of those devices without suffering a loss of data and/or capacity.

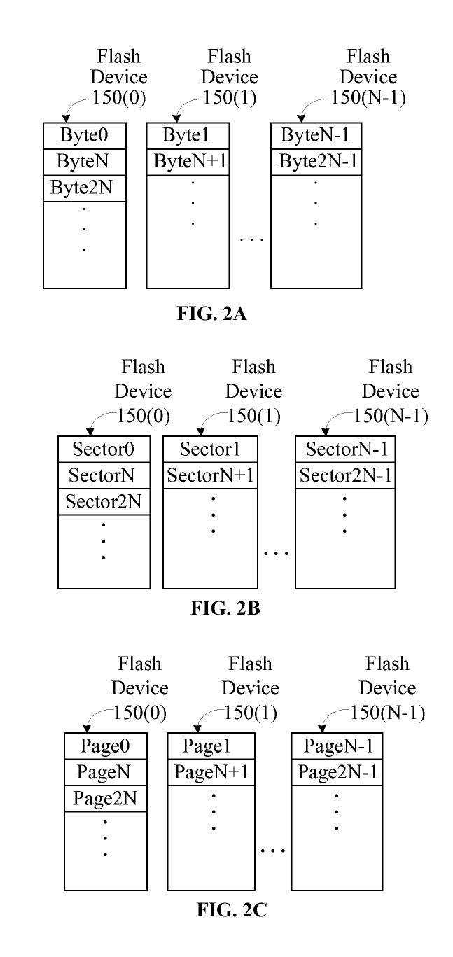

FIG. 2A illustrates an example striping configuration for flash devices 150(0) through 150(N−1). Flash devices 150(0) through 150(N−1) are organized in stripes, where a stripe includes a portion of each flash device in order to distribute the data across the flash devices 150(0) through 150(N−1). As shown in FIG. 2A, the data is striped with successive bytes of data being stored in different flash devices. For example, a first stripe includes Byte0, and Byte1 through ByteN−1. Similarly, a second strip includes ByteN and ByteN+1 through Byte2N−1. When the data is striped in bytes the effective sector size is N*S, where N is the number of flash devices and S is the sector size of the flash devices.

FIG. 2B illustrates another example striping configuration for flash devices 150(0) through 150(N−1). As shown in FIG. 2B, successive sectors of data are stored on different flash devices. For example, a first stripe includes Sector0, and Sector1 through SectorN−1. Similarly, a second strip includes SectorN and SectorN+1 through Sector2N−1. When the data is striped in sectors the effective sector size is S, the sector size of the flash devices.

FIG. 2C illustrates an example striping configuration for flash devices 150(0) through 150(N−1). As shown in FIG. 2C, successive pages of data are stored on different flash devices. For example, a first stripe includes Page0, and Page1 through PageN−1. Similarly, a second strip includes PageN and PageN+1 through Page2N−1. When the data is striped in pages the effective sector size is S, the sector size of the flash devices. In other embodiments of the present invention, successive blocks of the data are stored in different flash devices.

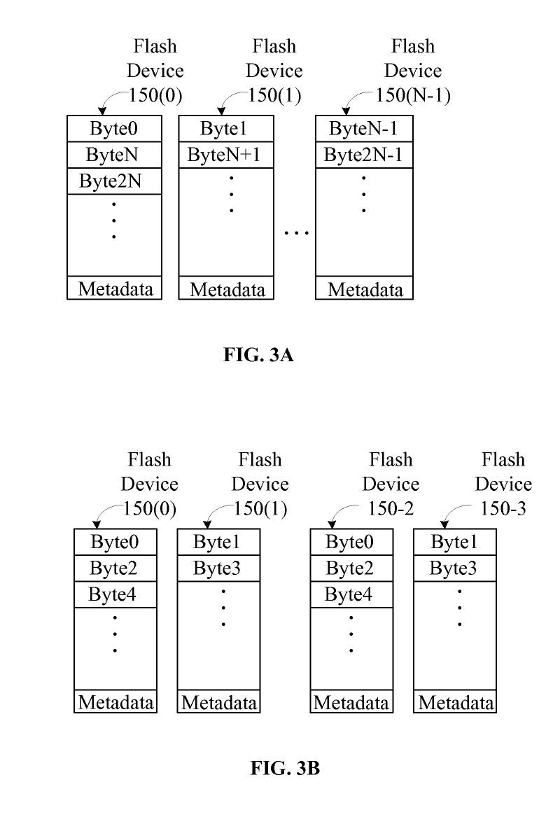

FIG. 3A illustrates an example byte striping configuration for the flash devices that is used to support RAID0 and RAID5 and higher. Although byte striping is shown in FIG. 3A, any other type of striping may be used, e.g., sector, page, block, and the like. When flash devices 150(0) through 150(N−1) are configured to support RAID0, no redundancy is used and error correction information is stored as metadata in each one of flash devices 150(0) through 150(N−1). The data is stored in a first portion of flash devices 150 and the metadata is stored in a second portion of flash devices 150.

When Flash devices 150(0) through 150(N−1) are configured to support RAID5, RAID6, RAID 10, RAID50, RAID60, and the like, parity is computed by flash storage controller 140 and stored as metadata in each one of flash devices 150(0) through 150(N−1). Alternatively, parity may be computed by CPU 120. Specifically, parity for the first stripe is computed as the XOR of Byte0, and Byte1 through ByteN−1 and stored as metadata in each one of flash devices 150(0) through 150(N−1). Parity is also computed for other stripes and stored as metadata. If any one of flash devices 150(0) through 150(N−1) is degraded, the data stored on that device may be recovered using the data stored on the other flash devices and the parity that was computed for the data. For example, Byte1 may be reconstructed by computing the XOR of parity for the first stripe, Byte0, and Byte2 through ByteN−1.

In some embodiments of the present invention, parity is computed by flash storage controller 140 and stored in some of the flash devices. For example, as shown in FIG. 1, parity may be stored in flash devices 160(0) through 160(M−1). In those embodiments the metadata stored in flash devices 150(0) through 150(N−1) may include wear leveling information, address translation information, bad sector information, directory information, journal data, and the like.

FIG. 3B illustrates an example byte striping configuration for the flash devices that are used to support RAID1. Although byte striping is shown in FIG. 3B, any other type of striping may be used. When flash devices 150(0), 150(1), 150(2), and 150(3) are configured to support RAID1, flash device 150(2) mirrors flash device 150(0) and flash device 150(3) mirrors flash device 150(1). Therefore, Byte0, Byte 2, and Byte4 are stored in flash device 150(0) and Flash device 150(2). Similarly, Byte1 and Byte3 are stored in Flash device 150(1) and Flash device 150(3). Error correction information is stored as metadata in each one of flash devices 150(0) through 150(3). Therefore, a first portion of flash devices 150 stores data and a second portion of flash devices 150 stores metadata. Error correction is performed by reading the mirror copy of the data. Bandwidth may be improved by reading alternate logical block addresses (LBA) or blocks of LBAs from the mirror copy.

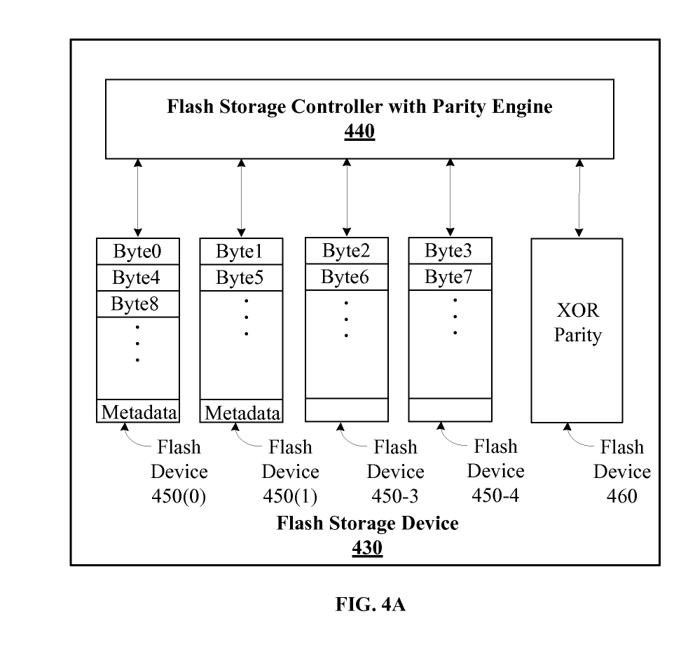

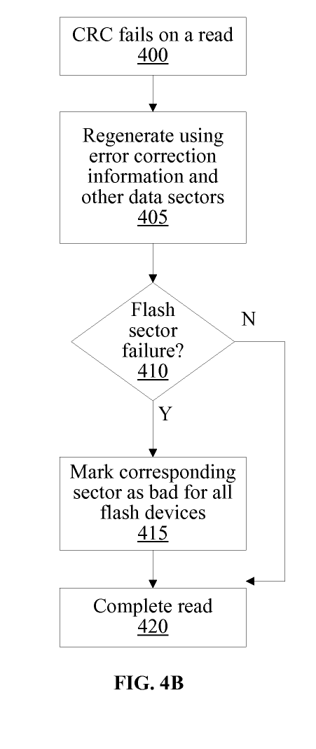

FIG. 4A is an example RAID configuration using flash devices 450(0), 450(1), 450(2), 450(3) and 460, in accordance with an embodiment of the method of the invention. The configuration shown in FIG. 4A may be used to support RAID3 in system 100 of FIG. 1. Flash device 460 stores XOR (exclusive OR) parity for each byte stripe of data stored in flash devices 450(0), 450(1), 450(2), and 450(3). Metadata stored in each flash device 450 may include bytes of cyclic redundancy check (CRC), address translation information, and bad sector information. Flash storage controller with parity engine 440 computes an XOR parity for four bytes at a time as data is written to a first portion of the flash devices, e.g., flash devices 450, and stores the XOR parity in a second portion of the flash devices, e.g., flash device 460. Flash storage controller with parity engine 440 determines if a CRC fails on a data read operation, and regenerates the missing data using the remaining data within the stripe and the parity for that stripe, as described in conjunction with FIG. 4B.

Flash storage controller with parity engine 440 configures a first portion of flash devices 450 and 460 to store data and configures a second portion of flash devices 450 and 460 to store error correction information. In some embodiments of the present invention, the second portion is distributed between all flash devices 450 and in other embodiments of the present invention, the second portion is stored in flash devices 460.

Although four flash devices 450 are shown in flash storage device 430 of FIG. 4A, in other embodiments of the present invention, additional flash devices 450 may be used. For example, when eight flash devices 150 are used and sector striped, the effective sector size is 4 Kbytes and error correction information is computed and stored in flash device 460. When long sector striping is used, the data is striped in 2 Kbyte sectors across flash devices 450 and error correction information is stored in flash device 460. In another embodiment of the present invention, Flash devices 450 may be MLC and flash device 460 may be SLC devices since MLC devices do not support partial writes needed for the XOR parity information.

FIG. 4B is a flow chart of operations for restoring data when RAID3 is used, in accordance with an embodiment of the method of the invention. In step 400 flash storage controller with parity engine 440 determines that CRC fails on a read of flash devices 450. In step 405 flash storage controller with parity engine 440 regenerates the data using the parity and other data sectors in the stripe. The parity is stored in a second portion of flash devices 150 and 160 or 450 and 460. In step 410 flash storage controller with parity engine 440 determines if there was a bad sector in one of the flash devices 450, and, if not, in step 420 the read operation is complete. Otherwise, in step 415 flash storage controller with parity engine 440 marks the corresponding sector as bad for all of the flash devices 450 in order to simplify the bad block management. In step 450 the read operation is complete.

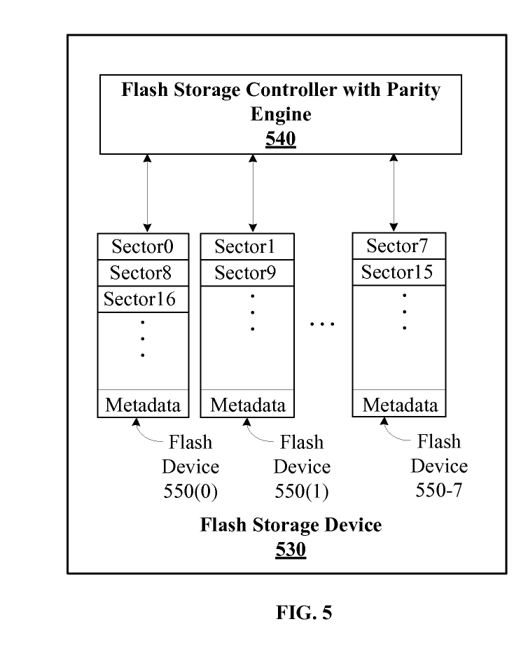

FIG. 5 is another example RAID configuration using flash devices 550(0), 550(1) through 550(7), and 560 in flash storage device 530, in accordance with an embodiment of the method of the invention. The configuration shown in FIG. 5 may be used to support RAID5 with sector striping. Metadata within each flash device 450 may include bytes of CRC, address translation information, and bad sector information. Flash storage controller with parity engine computes XOR (exclusive OR) parity for each byte stripe of data stored in flash devices 550 as data is written to flash devices 550 and stores the XOR parity as metadata in each flash device 450. Flash storage controller with parity engine 540 determines if a CRC fails on a data read operation, and regenerates the missing data using the remaining data within the stripe and the parity for that stripe, as described in conjunction with FIG. 4B.

One embodiment of the invention may be implemented as a program product for use with a computer system. The program(s) of the program product define functions of the embodiments (including the methods described herein) and can be contained on a variety of computer-readable storage media. Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored.

While the foregoing is directed to embodiments of the present invention, other and further embodiments of the invention may be devised without departing from the basic scope thereof, and the scope thereof is determined by the claims that follow. The foregoing description and drawings are, accordingly, to be regarded in an illustrative rather than a restrictive sense. The listing of steps in method claims do not imply performing the steps in any particular order, unless explicitly stated in the claim.

The invention claimed is:

1. A method for configuring multiple flash storage devices to form a single storage device, comprising:
configuring a first portion of the multiple flash storage devices to store data in stripes;
configuring a second portion of the multiple flash storage devices to store error correction information;
computing the error correction information for a stripe of data as the stripe of data is written to the first portion of the multiple flash storage devices; and
storing the error correction information for the stripe of data in the second portion of the multiple flash storage devices.

2. The method of claim 1, further comprising:
reading sectors of data from the first portion of the multiple flash storage devices;
determining a data read failure has occurred for a first sector of the sectors of data in a stripe; and
regenerating the first sector using the other sectors of the data and the error correction information for the stripe.

3. The method of claim 2, further comprising:
determining that the first sector results from a failure of a first flash storage device in the first portion of the multiple flash storage devices;
marking the first sector in the first flash storage device as bad; and
marking corresponding sectors in the other flash storage devices in the first portion of the multiple flash storage devices as bad.

4. The method of claim 1, wherein the first portion of the multiple flash storage devices and the second portion of the multiple flash storage devices are separate flash storage devices.

5. The method of claim 1, wherein the second portion of the multiple flash storage devices is distributed within the same flash storage devices that include the first portion of the multiple flash storage devices.

6. The method of claim 1, wherein the second portion of the multiple flash storage devices is configured to store wear leveling information.

7. The method of claim 1, wherein the stripe of data includes successive bytes of the data.

8. The method of claim 1, wherein the stripe of data includes successive pages of the data.

9. The method of claim 1, wherein the second portion of the multiple flash storage devices is configured to store bad sector information.

10. The method of claim 1, wherein the second portion of the multiple flash storage devices is configured to store address translation information.

11. A system for configuring multiple flash storage devices to form a single storage device, comprising:
the multiple flash storage devices including:
a first portion of the multiple flash storage devices configured to store data in stripes; and
a second portion of the multiple flash storage devices configured to store error correction information; and
a flash storage controller configured to:
store the data in the stripes in the first portion of the multiple flash storage devices;
compute the error correction information; and
store the error correction information in the second portion of the multiple flash storage devices.

12. The system of claim 11, wherein the flash storage controller is further configured to:
read sectors of data from the first portion of the multiple flash storage devices;
determine if a data read failure has occurred for a first sector of the sectors of data in a stripe; and
regenerate the first sector using the other sectors of the data and the error correction information for the stripe when the data read failure has occurred.

13. The system of claim 12, wherein the flash storage controller is further configured to:
determine that the first sector results from a failure of a first flash storage device in the first portion of the multiple flash storage devices;
mark the first sector in the first flash storage device as bad; and
mark corresponding sectors in the other flash storage devices in the first portion of the multiple flash storage devices as bad.

14. The system of claim 11, wherein the first portion of the multiple flash storage devices and the second portion of the multiple flash storage devices are separate flash storage devices.

15. The system of claim 11, wherein the second portion of the multiple flash storage devices is distributed within the same flash storage devices that include the first portion of the multiple flash storage devices.

16. The system of claim 11, wherein the second portion of the multiple flash storage devices is configured to store wear leveling information.

17. The system of claim 11, wherein the stripe of data includes successive bytes of the data.

18. The system of claim 11, wherein the stripe of data includes successive blocks of the data.

19. The system of claim 11, wherein the second portion of the multiple flash storage devices is configured to store bad sector information.

20. The system of claim 11, wherein the second portion of the multiple flash storage devices is configured to store address translation information.
